(19) United States
(12) Patent Application Publication
(10) Pub. No.: US 2024/0371607 A1
(43) Pub. Date: Nov. 7, 2024

(54) PRESSURE SEAL METHOD AND APPARATUS

(71) Applicant: Applied Materials, Inc., Santa Clara, CA (US)

(72) Inventor: Vijay D. PARKHE, San Jose, CA (US)

(21) Appl. No.: 18/630,827

(22) Filed: Apr. 9, 2024

Related U.S. Application Data
(60) Provisional application No. 63/499,913, filed on May 3, 2023.

(51) Int. Cl. H01J 37/32; H01L 21/683

(52) U.S. Cl. CPC H01J 37/32513; H01L 21/6833; H01J 37/32715; H01J 2237/2007

(57) ABSTRACT

An apparatus and method for a pressure seal in a substrate support assembly are disclosed herein. In one example, an apparatus for pressure containment comprises a metal core ring configured to be disposed within a housing of a substrate pedestal and an outer coating disposed on an exterior surface of the metal core operable to withstand a pressure of about 125 newton/millimeter² or below, the outer coating operable to deform about 2 microns to about 40 microns to create a pressure seal within the housing.

### RELATED APPLICATIONS

This application claims benefit from U.S. Provisional Application Ser. No. 63/499,913, filed May 3, 2024, which is incorporated herein by reference in its entirety.

### BACKGROUND

### Field

Embodiments of the present disclosure generally relate to a semiconductor vacuum seal and system for the same. More specifically, embodiments of the disclosure relate to a metal seal capable of withstanding high temperature.

### Description of the Related Art

In semiconductor manufacturing, integrated circuits (IC) are formed on semiconductor substrates through various manufacturing steps, including pressure and temperature control of the processing chamber. Conventional sealing of chamber components, such as the electrostatic chuck vacuum seals, utilize organic seals that degrade against variations of high pressure, high temperature, and when exposed to fluorine environments within chamber processes. Alternatively, copper seals have been utilized however copper requires extremely high pressure and there may be undesired copper exposure. These organic or copper seals may dry, deform, or break to allow for undesired pressure equalization at, for example, a temperature in excess of 350 degrees Celsius. These organic or copper vacuum seal components limitations may lead to poor chamber performance and substrate processing waste at high temperature chamber operations. Thus, there is a need for improved sealing of the electrostatic chuck technique for elevated pressure and temperature with in a processing chamber.

### SUMMARY

An apparatus and method for a pressure seal in a substrate support assembly are disclosed herein. In one example, an apparatus for pressure containment comprises a metal core ring configured to be disposed within a housing of a substrate pedestal and an outer coating disposed on an exterior surface of the metal core ring operable to withstand a pressure of about 125 newton/millimeter² or below, the outer coating operable to deform about 2 microns to about 40 microns to create a pressure seal within the housing.

In another example, a method of making a pressure seal for semiconductor processing comprises positioning a coated metal seal ring in a substrate pedestal housing and deforming an outer surface of the coated metal seal ring by applying a pressure to at least a top surface and a bottom surface of the coated metal seal ring to create a pressure seal within the substrate pedestal housing, the pressure being about 50 to about 75 newton/millimeter².

In yet another example, an apparatus in semiconductor processing for pressure containment is provided. The apparatus includes a metal core ring comprising stainless steel or Inconel, the metal core configured to be disposed within a housing of a substrate pedestal and an outer coating disposed directly on the metal core ring, the outer coating comprising aluminum, indium, or magnesium alloy, the outer coating operable to withstand a pressure of about 10 newton/millimeter² to about 75 newton/millimeter², the outer coating operable to deform about 2 microns to about 20 microns to create a pressure seal within the housing.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic cross-sectional of an exemplary processing chamber, according to certain embodiments of the present disclosure.

FIG. 2 is a schematic cross-sectional view of an exemplary pressure seal, according to certain embodiments of the present disclosure.

FIG. 3 is a schematic cross-sectional view of an exemplary pressure seal using foil gaskets, according to one embodiment of the present disclosure.

FIG. 4 illustrates a block diagram representing a method to create a pressure seal, according to certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

Many of the details, dimensions, angles, and other features shown in the Figures are merely illustrative of particular implementations. Accordingly, other implementations can have other details, components, dimensions, angles, and features without departing from the spirit or scope of the present disclosure. In addition, further implementations of the disclosure can be practiced without several of the details described below

### DETAILED DESCRIPTION

Disclosed herein is a coated metal pressure seal for a substrate support assembly disposed within a semiconductor processing chamber. The pressure seal protects an interior volume of a processing chamber, which is maintained under vacuum, against vacuum leaks from an atmospheric environment within the substrate support assembly. The coated metal pressure seal is particularly advantageous for electrostatic chuck (ESC) applications that are exposed to high temperature operations such as in excess of about 350 degrees Celsius. The pressure seal is disposed at the interfaces between the atmospheric spaces within the substrate support assembly and the interior volume of the processing chamber to prevent leakage into the vacuum environment.

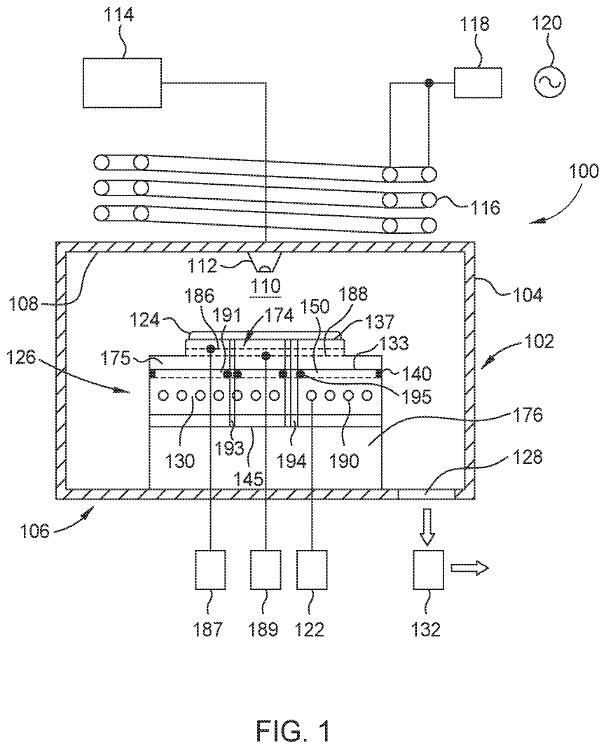

FIG. 1 is a schematic cross-sectional view of an exemplary plasma processing chamber 100, shown configured as an etch chamber, having a substrate support assembly 126. The substrate support assembly 126 may be utilized in other types of processing plasma chambers, for example plasma treatment chambers, annealing chambers, physical vapor deposition chambers, chemical vapor deposition chambers, cryogenic chambers, and ion implantation chambers. The processing chamber 10 may also be adapted to be used as other systems where the ability to control processing uniformity for a surface or workpiece, such as a substrate, is desirable. Controlling of the dielectric properties, such as dielectric loss, and volume resistivity, of the substrate support at elevated temperature ranges beneficially enables azimuthal processing uniformity for a substrate 124 being processed thereon.

The plasma processing chamber 100 includes a chamber body 102 having sidewalls 104, a bottom 106, and a lid 108 that encloses a processing region 110. An injection apparatus 112 is coupled to the sidewalls 104 and/or lid 108 of the chamber body 102. A gas panel 114 is coupled to the injection apparatus 112 to allow process gases to be provided into the processing region 110. The injection apparatus 112 may be one or more nozzle or inlet ports, or alternatively a showerhead. Processing gas, along with any processing by-products, are removed from the processing region 110 through an exhaust port 128 formed in the sidewalls 104, or bottom 106, of the chamber body 102. The exhaust port 128 is coupled to a pumping system 132, which includes throttle valves and pumps utilized to control the vacuum levels within the processing region 110.

The processing gas may be energized to form a plasma within the processing region 110. The processing gas may be energized by capacitively or inductively coupling RF power to the processing gases. In the embodiment depicted in FIG. 1, a plurality of coils 116 are disposed above the lid 108 of the plasma processing chamber 100 and coupled through a matching circuit 118 to an RF power source 120.

The substrate support assembly 126 is disposed in the processing region 110 below the injection apparatus 112. The substrate support assembly 126 includes an electrostatic chuck 174 and a cooling plate 130. The cooling plate 130 is supported by a base plate 176. The base plate 176 is supported by one of the sidewalls 104, or bottom 106, of the processing chamber. The substrate support assembly 126 may additionally include a heater assembly (not shown), such as a ceramic heater. Additionally, the substrate support assembly 126 may include a facility plate 145 and/or an insulator plate (not shown) disposed between the cooling plate 130 and the base plate 176.

The cooling plate 130 may be formed from a metal material or other suitable material. For example, the cooling plate 130 may be formed from aluminum (Al). The cooling plate 130 may include cooling channels 190 formed therein. The cooling channels 190 may be connected to a heat transfer fluid source 122. The heat transfer fluid source 122 provides a heat transfer fluid, such as a liquid, gas, or a combination thereof, which is circulated through one or more cooling channels 190 disposed in the cooling plate 130. The fluid flowing through neighboring cooling channels 190 may be isolated to enabling local control of the heat transfer between the electrostatic chuck 174 and different regions of the cooling plate 130, which assists in controlling the lateral temperature profile of the substrate 124. In one embodiment, the heat transfer fluid circulating through the cooling channels 190 of the cooling plate 130 maintains the cooling plate 130 at a temperature between about 90 degrees Celsius and about 80 degrees Celsius, or at a temperature lower than 90 degrees Celsius.

The electrostatic chuck 174 includes a chucking electrode 186 disposed in a dielectric body 175. The dielectric body 175 has a workpiece support surface 137 and a bottom surface 133 opposite the workpiece support surface 137. The dielectric body 175 of the electrostatic chuck 174 may be fabricated from a ceramic material, such as alumina (Al₂O₃), aluminum nitride (AlN) or other suitable material. Alternately, the dielectric body 175 may be fabricated from a polymer, such as polyimide, polyetheretherketone, polyaryletherketone and the like.

The dielectric body 175 may also include one or more resistive heaters 188 embedded therein. The resistive heaters 188 may be provided to elevate the temperature of the substrate support assembly 126 to a temperature suitable for processing a substrate 124 disposed on the workpiece support surface 137 of the substrate support assembly 126. The resistive heaters 188 are coupled through the facility plate 145 to a heater power source 189. The heater power source 189 may provide 900 watts or more power to the resistive heaters 188. A controller (not shown) may control the operation of the heater power source 189, which is generally set to heat the substrate 124 to a predefined temperature. In one embodiment, the resistive heaters 188 include a plurality of laterally separated heating zones, wherein the controller enables at least one zone of the resistive heaters 188 to be preferentially heated relative to the resistive heaters 188 located in one or more of the other zones. For example, the resistive heaters 188 may be arranged concentrically in a plurality of separated heating zones. The resistive heaters 188 may maintain the substrate 124 at a temperature suitable for processing. In some embodiments utilizing elevated processing temperatures, the resistive heaters 188 may maintain the substrate 124 at a temperature between about 180 degrees Celsius to about 500 degrees Celsius.

The electrostatic chuck 174 generally includes a chucking electrode 186 embedded in the dielectric body 175. The chucking electrode 186 may be configured as a mono-polar or bipolar electrode, or other suitable arrangement. The chucking electrode 186 is coupled through an RF filter to a chucking power source 187, which provides a RF or DC power to electrostatically secure the substrate 124 to the workpiece support surface 137 of the electrostatic chuck 174. The RF filter prevents RF power utilized to form a plasma (not shown) within the plasma processing chamber 100 from damaging electrical equipment or presenting an electrical hazard outside the chamber.

The workpiece support surface 137 of the electrostatic chuck 174 may include gas passages 194 for providing backside heat transfer gas to the space between the substrate 124 and the workpiece support surface 137 of the electrostatic chuck 174. The electrostatic chuck 174 may also include lift pin holes for accommodating lift pins 193 for elevating the substrate 124 above the workpiece support surface 137 of the electrostatic chuck 174 to facilitate robotic transfer into and out of the plasma processing chamber 100.

A bonding layer 150 is disposed between the electrostatic chuck 174 and the cooling plate 130 as depicted in FIG. 1. The bonding layer 150 may be formed from several layers which provide for different thermal expansions of the electrostatic chuck 174 and the cooling plate 130. In some embodiments, the bonding layer 150 includes an adhesive layer and a seal ring 140. The seal ring 140 is configured to protect the adhesive material forming the bonding layer 150 disposed between the electrostatic chuck 174 and the cooling plate 130 from the gases and plasma present in the processing region 110. The seal ring 140 may also be configured to prevent the processing region 110 from a vacuum leak. In some embodiments, the seal ring 140 may be omitted.

The inner components of the substrate support assembly 126, such as the gas passages 194 or the lift pins 193 and its dedicated actuator (not shown) may operate at a different pressure than the vacuum conditions within the processing region 110, thereby necessitating a pressure isolation seal. For example, the pressure of the inner components may be atmospheric or at a pressure above atmospheric. An exemplary interface point between the differing pressure locations are shown by interface points 191, such as around the lift pins 193 or around the gas channels 194. The interface points 191 are the locations where regions of different pressures meet with each other. Thus, a pressure seal 195 is strategically placed for pressure isolation of the processing region 110 from the higher pressure locations exterior to the processing region 110. The interface points 191 may be present within certain other locations of the substrate support assembly 126, such as the seal ring 140.

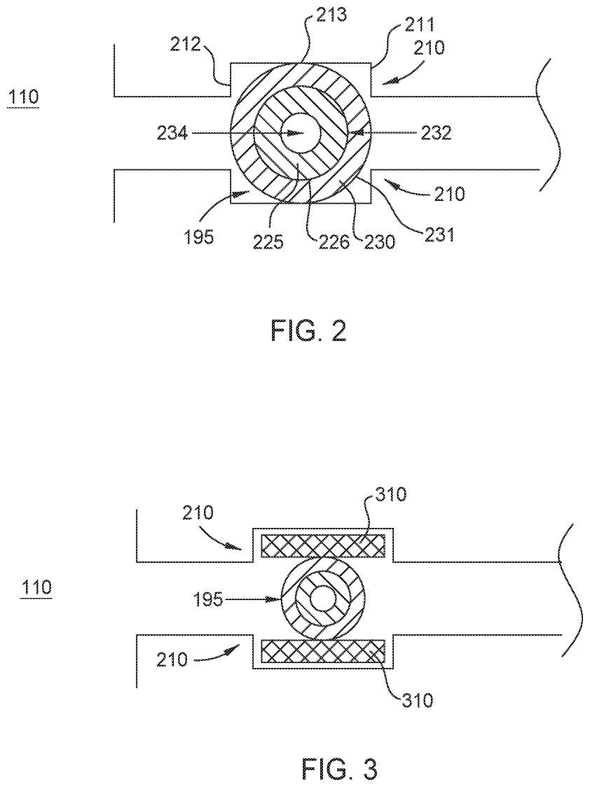

FIG. 2 depicts a schematic cross-sectional view of an exemplary pressure seal 195 within a housing 210 located at one of the interface points 191. The housing 210 is depicted as a substantially square housing but it is contemplated that the shape of the housing 210 may be rounded, substantially flat, or elliptical. The housing 210 may also be shaped as a portion of an o-ring groove. Each housing 210, either top or bottom as shown in FIG. 2, will have an inner side wall 211, an outer side wall 212, and a recessed surface 213. The housing sidewalls, 211, 212, or the recessed surface 213 contact the pressure seal 195 to form an adequate barrier against pressure equalization or vacuum loss within the chamber.

The pressure seal 195 includes a hollow center 234, a metal core 225 and an outer coating 230. An optional inner coating 232 may be disposed between the metal core 225 and the outer coating 230. The metal core 225 is depicted as a hollow o-ring. It is contemplated that the profile shape of the metal core 225 may be an s-shape, c-shape, u-shape, k-shape, solid circle, or other suitable shape that can receive the outer coating 230 while be disposed in the housing 210. It is understood that the pressure seal 195 may be of various sizes, i.e. diameters or other shape, to accommodate the configuration of the interface point 191 which demarks the location of the pressure seal 195. For example, a pressure seal 195 may be placed around the lift pin area which would be significantly smaller than a pressure seal 195 that is used around the entire perimeter of the substrate support assembly 126. In one example, the material of metal core 225 is stainless steel, a super alloy such as nickel-based super alloy (for example INCONEL®), or the like. The metal core 225 provides a rigid and elastic core structure within the pressure seal 195 while being able to withstand about 125 newton/millimeter² or below force desired for securing the housing 210 of the substrate support assembly 126 of FIG. 1. The metal core has an outer surface 226 configured to adhere with the outer coating 230. The outer surface 226 may be smooth or conditioned to a desired roughness for an improved adhesion of the outer coating 230 to the outer surface 226. In one example, the outer surface 226 may have a roughness of less than 8 RA microinches. In another example, the outer surface 226 may have a roughness of between 16 Ra microinches and 32 Ra microinches, or other different roughness. A suitable manner to achieve desired surface roughness includes emery buffing, lapping, and honing, among others.

The metal core 225 is externally enveloped by the outer coating 230. In some embodiments, the outer coating 230 is electrodeposited on the metal core 225 by a controlled electrolysis, i.e. electroplating. In other embodiments the outer coating 230 is deposited by plasma spray techniques comprising a thermal spray coating utilizing a plasma spray torch to generate the plasma with controlled oxidation. The outer coating 230 may be applied by other techniques. The outer coating 230 is softer or more malleable than the metal core 225. Stated differently, the metal core 225 has a hardness greater than that of the outer coating 230. The outer coating 230 is applied to a desired thickness of about 1-40 microns, such as about 2-20 microns. The outer coating 230 may be an alloy, for example, aluminum alloy, indium, magnesium alloy, aluminum magnesium alloy or a mixture of a low percentage nickel in combination with the aforementioned alloys. In some embodiments, silicon is mixed with the above-listed alloy to reduce the melting point of the alloy selected. The material of the outer coating 230 has the benefit of having a melting temperature in excess of 350 degrees Celsius while also being compatible with fluorine. It is understood that fluorine compatibility means that the outer coating 230 of the seal 195 is sufficiently stable with fluorine exposure as to not compromise the seal 195 and allow leakage via the interface points 191. The outer coating 230 has a service temperature of at least 350 degrees Celsius, such as greater than 350 degrees Celsius, such as greater than 375 degrees Celsius, such as greater than 400 degrees Celsius, such as greater than 450 degrees Celsius, such as greater than 500 degrees Celsius, such as greater than 550 degrees Celsius, such as within a range of about 350 degrees Celsius to about 550 degrees Celsius.

The outer coating 230 has an exterior surface 231 that may be smooth or conditioned to a desired roughness for increased contact with the housing 210. In one example, the exterior surface 231 may have a roughness of less than 8 RA microinches. In another example, the exterior surface 231 may have a roughness of between 16 Ra microinches and 32 Ra microinches, or other different roughness. A suitable manner to achieve desired surface roughness includes emery buffing, lapping, and honing, among others.

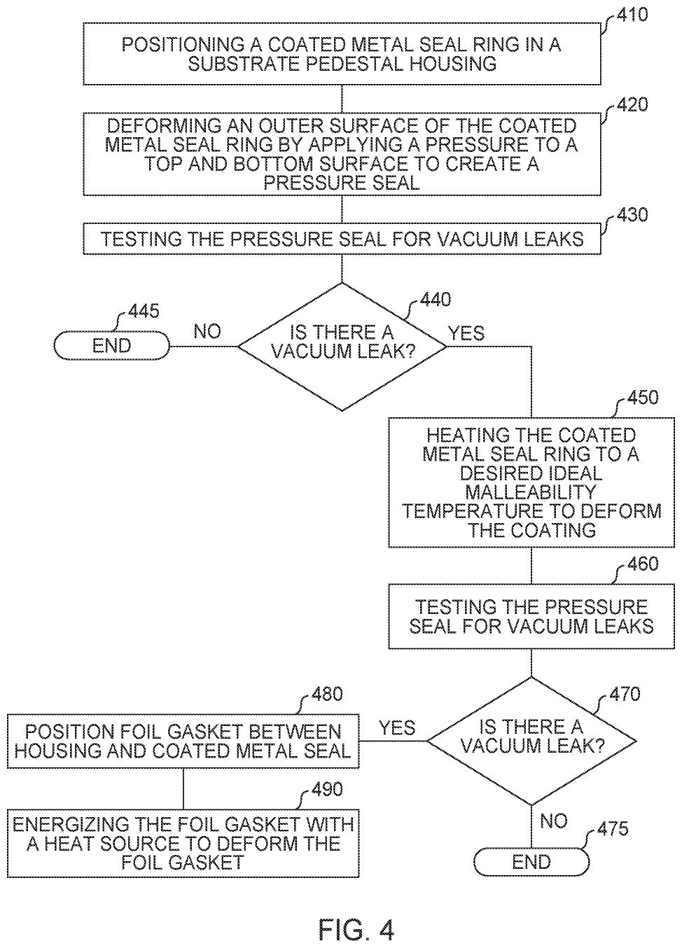

FIG. 3 depicts a schematic cross-sectional view of an exemplary pressure seal using an optional foil gasket 310 within the housing 210 utilizing the pressure seal 195 mentioned above. In some applications, the foil gasket 310 is utilized to bond the pressure seal 195 to the housing 210 to obtain a bonded pressure seal. The foil gasket 310 may be made aluminum and/or nickel. In one example, the foil gasket 310 has multiple alternating layers of aluminum and nickel foils. The foil gasket 310 is placed into the housing 210 so that the foil gasket 310 is sandwiched between the pressure seal 195 and a surface of the housing 210. The foil gasket 310, in an embodiment, may be energized to bond the pressure seal 195 to the housing 210 using an external electrical source coupled to the foil gasket 310, a battery, such as nine volt battery, or the like. In another embodiment, the foil gasket 310 may be energized by a heating of the processing chamber, such as the ceramic heater. The foil gasket 310 is deformable to create a bonded pressure seal between the housing 210 and the seal 195. A bonded pressure seal is understood to be a chemical or thermal bonding of the pressure seal 195 to the housing 210 via the gasket 310. When bonding the pressure seal 195 to the housing 210, the foil gasket 310 is deformed about 1 micron to about 40 microns to sufficiently conform to the roughness of the housing 210. In some embodiments, the deformed foil gasket 310 wrapped around the exterior surface of the outer coating. It is contemplated that the foil gasket 310 may be embedded within or inside an opening of a c-shaped metal core to help heat the core and the outer coating to a desired temperature.

FIG. 4 depicts an exemplary method 400 to create a pressure seal described above. At operation 410, a seal is positioned in the housing. The foil may optionally be disposed between the seal and housing. At operation 420, a pressurizing operation is performed that deforms the outer surface of the pressure seal. At operation 430, the interface between the seal and the housing is tested for vacuum leak operation. At operation 440, the result of the testing for vacuum leaks in operation 430 is determined. At operation 445, the method 400 ends if no leaks are determined at operation 440. If presence of a leak is determined at operation 440, a heating operation is performed at operation 450. After completion of operation 450, a second test for vacuum leak is performed at operation 460. At operation 470, the result of the testing for vacuum leaks in operation 460 is determined. At operation 475, the method 400 ends if no leaks are determined at operation 470. If presence of a leak is determined at operation 470, the method 400 continues at operation 480 by positioning a foil gasket between the seal and housing. At operation 490, the foil gasket is bonded to the housing to create a bonded pressure seal.

Operation 410 includes positioning the pressure seal 195 of FIG. 2, referred as the coated metal seal ring within the discussion of FIG. 4, within the substrate support assembly, or electrostatic chuck assembly. The coated metal seal ring may reside within a substrate assembly housing described above. Once positioned, a pressure of about 50 newton/millimeter² to about 75 newton/millimeter² is exerted onto the coated metal seal ring by compression. The compression is achieved by tightening down the upper housing down towards the direction of the lower housing, or vice versa, causing the coated metal seal ring to be compressed on at least the upper and lower surface equally. This pressure compression may create an adequate pressure seal capable of preventing vacuum leaks.

Operation 430 is a test for pressure leaks. As previously mentioned, the chamber volume generally operates at a pressure near full vacuum or at least sub-atmospheric pressure. The chamber may be pumped down through a vacuum or turbo pump coupled to the chamber interior. Operation 440 is a decision block that enables an operator to proceed to the following operation based on whether the vacuum environment created for testing for a vacuum leak fails or not. When the test proves that no leak is present near the coated metal seal ring and its housing, then operation 445 ends method 400 as the pressure seal is adequate to withstand that vacuum environment while exhibiting resilience in temperatures exceeding at least 350 degrees Celsius. When a vacuum leak is determined at operation 440, the operator may proceed to operation 450.

Operation 450 is a deformation operation that include heating the coated metal seal ring to about two-thirds (⅔) of the melting temperature, in absolute, of the coating of the coated metal seal ring. For example, the below formula reveals the targeted softening temperature for the coating of the coated metal seal ring to have an acceptable malleability to deform the coating of the coated metal seal ring.

$$Targeted Malleability Temperature ( Celcius ) = \frac{2}{3} ( TM + 273 ) - 273 \qquad Eq . ( 1 )$$

Where:
   TM=Material Melting Point (Celsius)

For example, in some embodiments the coating comprises aluminum. Aluminum has a melting point temperature of about 660 degrees Celsius. By use of Eq. (1) the targeted temperature for aluminum malleability is about 349 degrees Celsius. Therefore, on such embodiments where the coating is aluminum, the targeted heating temperature of operation 450 would be about 349 degrees Celsius. Similar calculations may be performed for the coating material selected. For example, a magnesium coated metal ring seal (magnesium has melting point of 650 degrees Celsius) would entail heating to 342 degrees Celsius for targeted deforming temperature. In a similar fashion, mixed properties can be determined to find the targeted deforming temperature regardless of the percentages of aluminum or magnesium alloy used.

Upon heating the coated metal seal ring in operation 450, a vacuum seal may be formed. Operation 460 is a second test for pressure leaks. The chamber may be pumped down through a vacuum pump coupled to the chamber interior. Operation 470 is a decision block to determine which operations should be performed if a vacuum leak is or is not detected. When the test proves that no leak is present near the coated metal seal ring and its housing, then operation 475 ends the method 400 as the pressure seal is adequate to withstand that vacuum environment. When a vacuum leak is determined at operation 470, the method 400 proceeds to operation 480.

Operation 480 include adding a foil gasket as described in FIG. 3, positioned above and or below the coated metal seal ring within the housing. The foil gasket is operable to be heated to deform about 1 micron to about 40 microns to make a bonded seal to both the housing and the coated metal seal ring. The bonded seal occurs during operation 490 where the foil gasket 310 is energized by a dedicated heater or the electrostatic chuck. After the foil gasket is energized and heat is produced to heat the foil gasket to deform to couple with the roughness of both the housing and the exterior surface of the coated metal seal ring. Operation 480 ensures a bonded seal is created.

The above embodiments have been described as a pressure seal suitable for an elevated temperature chamber process. In another embodiment, a similar construction of a coated metal seal ring includes an inner coating disposed between the outer coating and the metal core of FIGS. 2 and 3. The coated metal seal ring having the inner coating can be used for fluorine containing cryogenic applications. In some embodiments, the thickness of the outer coating is about 0.02 microns. In one example, the inner coating is indium or similar material. For indium embodiments, the pressure applied to the pressure seal may be between about 10 newton/millimeter² to about 75 newton/millimeter², such as about 10 newton/millimeter² to about 30 newton/millimeter². Indium has a melting point about 156 degrees Celsius. By heating the pressure seal as described above, the indium inner coating will easily deform to provide an excess of deformable area to aid in the creation of the seal. It is understood that the outer coating with a thickness of about 0.02 microns will deform in a similar manner, such as a conformal deformation, as the inner coating is deformed under the same conditions of the inner coating. In yet another embodiment, the pressure seal can be used for non-fluorine containing cryogenic applications where the coating of the metal seal ring is indium. It is contemplated the creation of the seal is similar to those of the elevated temperature chamber processes however, the indium enables the seal to be utilized within a cryogenic process.

All numerical values are “about” or “approximately” the indicated value, and take into account experimental error and variations that would be expected by a person having ordinary skill in the art.

While the foregoing is directed to embodiments of the present disclosure, other and further embodiments of the disclosure may be devised without departing from the basic scope thereof, and the scope thereof is determined by the claims that follow. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby.

Certain embodiments and features have been described using a set of numerical minimum values and a set of numerical maximum values. It should be appreciated that ranges including the combination of any two values, e.g., the combination of any minimum value with any maximum value, the combination of any two minimum values, and/or the combination of any two maximum values are contemplated unless otherwise indicated. Certain minimum values, maximum values, and ranges appear in one or more claims below.

What is claimed is:

1. A seal assembly for containing pressure during a semiconductor, the seal assembly comprising:
a metal core configured to be disposed within a housing of a substrate pedestal; and
an outer coating disposed on an exterior surface of the metal core operable to withstand a pressure of about 125 newton/millimeter² or below, the outer coating capable of being deformed by about 2 microns to about 40 microns to create a pressure seal within the housing.

2. The seal assembly of claim 1, wherein the metal core has a hardness greater than a hardness of the outer coating.

3. The seal assembly of claim 2, wherein the outer coating comprises aluminum, magnesium, indium, or their alloys.

4. The seal assembly of claim 3, wherein the metal core comprises stainless steel or a nickel-based supper alloy.

5. The seal assembly of claim 1, further comprising an inner coating disposed between the outer coating and the metal core.

6. The seal assembly of claim 5, wherein the inner coating comprises indium.

7. The seal assembly of claim 1, further comprising an inner coating disposed between the outer coating and the metal core, the outer coating and the inner coating capable of being deformed at a same malleability temperature.

8. The seal assembly of claim 1, further comprising at least one foil gasket disposed between the housing and the outer coating, the foil gasket capable of being deformed by about 2 microns to about 40 microns when bonding to the housing.

9. The seal assembly of claim 8, wherein the at least one foil gasket comprises aluminum and nickel.

10. A method of making a pressure seal for a processing chamber, the method comprising;
positioning a coated metal seal ring in a substrate pedestal housing; and
deforming an outer surface of the coated metal seal ring by applying a pressure to at least a top surface and a bottom surface of the coated metal seal ring to create a pressure seal within the substrate pedestal housing, the pressure being about 50 newton/millimeter² to about 75 newton/millimeter².

11. The method of claim 10, further comprising testing the pressure seal for vacuum leaks.

12. The method of claim 10, further comprising heating the coated metal seal to a targeted malleability temperature to deform the outer surface by about 1 microns to about 40 microns while the pressure is applied.

13. The method of claim 12, further comprising testing the pressure seal for vacuum leaks.

14. The method of claim 12, wherein the heating the coated metal seal is implemented by a ceramic heater of the processing chamber.

15. The method of claim 10, further comprising:
positioning foil gaskets on the top surface and the bottom surface of the coated metal seal ring; and
energizing the foil gaskets with an electrical source to force a deformation of about 2 to about 40 microns, the deformed foil gaskets forming a pressure seal in the substrate pedestal housing.

16. The method of claim 15, wherein the energizing the foil gaskets is implemented by a battery.

17. The method of claim 15, wherein the foil gaskets comprise aluminum and nickel layers.

18. An apparatus in semiconductor processing for pressure containment, the apparatus comprising:
a metal core comprising stainless steel or a nickel-based supper alloy, the metal core being disposed within a housing of a substrate pedestal; and
an outer coating disposed directly on the metal core, the outer coating comprising aluminum or magnesium alloy, the outer coating capable of withstanding a pressure of about 10 newton/millimeter² to about 75 newton/millimeter², the outer coating capable of being deformed by about 2 microns to about 20 microns to create a pressure seal within the housing.

19. The apparatus of claim 18, further comprising:
an inner coating comprising indium and disposed between the outer coating and the metal core, the outer coating and the inner coating capable of being deformed at a same malleability temperature.

20. The apparatus of claim 18, further comprising at least one foil gasket disposed between a surface of the housing and the outer coating, the foil gasket capable of being deformed by about 2 microns to about 40 microns when forming a bond to the housing.
